(19) United States
(12) Patent Application Publication
(10) Pub. No.: US 2019/0093829 A1
(43) Pub. Date: Mar. 28, 2019

(54) SYSTEM AND METHOD FOR DETECTING AND REMEDIATING SELECTIVE SEAM WELD CORROSION IN A CONDUIT

(71) Applicant: KPL South Texas, LLC, Wichita, KS (US)

(72) Inventors: Jim Andrew, Wichita, KS (US); James Simek, Sandy, UT (US)

(73) Assignee: KPL South Texas, LLC, Wichita, KS (US)

(21) Appl. No.: 16/135,215

(22) Filed: Sep. 19, 2018

Related U.S. Application Data
(60) Provisional application No. 62/562,097, filed on Sep. 22, 2017.

(51) Int. Cl. F17D 5/00; G01N 27/87; G01R 1/06; G08B 21/18; G08B 23/00

(52) U.S. Cl. CPC F17D 5/005; G01N 27/87; G08B 23/00; G08B 21/18; G01R 1/06

(57) ABSTRACT

Embodiments related to a system and method for detecting and remediating selective seam weld corrosion in conduits such as steel pipes that transport oil and gas products. In particular, a probe detects magnetic flux leakage in at least two orientations. Anomalies in the conduit are then identified and assessed for selective seam weld corrosion based on factors that include the magnetic flux leakage detection and the depth of the anomalies. For certain categories of assessed anomalies, the corresponding portions of the conduit are selectively remediated in accordance with these factors.

### CROSS-REFERENCE TO RELATED APPLICATIONS

This application claims priority to U.S. Provisional Application No. 62/562,097, filed on Sep. 22, 2017. The disclosure of the above application is incorporated by reference in its entirety.

### BACKGROUND

Conduits such as pipes carrying oil and gas products are often made of materials such as steel. Over time, these steel pipes can begin to corrode and weaken the pipes. If left unrepaired, the corroded pipes can leak or burst, causing their contents to spill into the environment.

One type of corrosion that can be particularly problematic in terms of compromising the integrity of the pipe and difficulty of identification is known as selective seam weld corrosion (SSWC). SSWC forms along the seam of the pipe where, during the formation of the pipe, the ends of the rolled steel were joined and welded together. Referring to FIG. 1A, this seam (also known as the bondline) is shown at 102.

Since SSWC can have a particularly negative effect on pipe integrity, it is clearly important to quickly identify the existence of SSWC within a pipe. This has often been accomplished using probes that travel within the pipe and convey information that allow a decision to be made regarding whether to excavate and more closely examine/replace a potentially compromised section of pipe. While identifying SSWC is important, it is also important not to mistake a more benign form of corrosion for SSWC, since excavating and replacing a section of pipe can be a costly endeavor.

Generally, probes that magnetize and then detect magnetic flux leakage in a pipe have been used to detect volumetric metal loss anomalies, provided the anomaly disrupts lines of magnetic flux. These probes commonly only detect axially-aligned magnetic flux leakage. Since SSWC forms as an axially-aligned narrow slit (i.e., along the seam of the pipe), the axially-aligned lines of magnetic flux created by these probes may not be disrupted, and thus SSWC may not be detected by such probes. To help rectify this issue, other probes have been developed that magnetize the pipe across the seam and thus can detect circumferential magnetic flux leakage (at substantially 90 degrees to the seam weld) and/or spiral (helical) magnetic flux leakage (SMFL) relative to the seam weld (which can be at, e.g., 25 degrees to the seam weld). As shown in FIG. 1B, an anomaly is shown as having the SSWC component as a long slit 152 as well as a more volumetric component 150 that often accompanies the existence of SSWC. Also shown are the directions of the axially-aligned magnetic flux as well as the spiral and circumferential magnetic flux (the latter two being more definitively disrupted by the SSWC). These multi-orientational probes can provide datasets relating to disruptions of each aforementioned magnetic flux orientations.

Conventionally, the data provided by the probes is graphed in some manner and then visually inspected by human subject matter experts. These experts then decide whether a particular anomaly detected by this data is sufficiently likely to be SSWC to warrant excavating the section of pipe containing the anomaly. This is a slow, expensive process that, depending on the number of experts involved over a given timeframe, can be fraught with inconsistencies. These inconsistencies and other factors associated with this process can also result in pipes being excavated or otherwise removed from service unnecessarily, causing the needless expenditure of millions of dollars.

### SUMMARY

Embodiments related to a system and method for detecting and remediating SSWC in conduits such as steel pipes that transport oil and gas products. In particular, a probe detects magnetic flux leakage in at least two orientations. Anomalies in the conduit are then identified and assessed for SSWC based on factors that include the magnetic flux leakage detection and the depth of the anomalies. For certain categories of assessed anomalies, the corresponding portions of the conduit are selectively remediated in accordance with these factors.

### BRIEF DESCRIPTION OF THE FIGURES

FIG. 1A depicts a diagram of an example probe traveling in a conduit, in embodiments.

FIG. 1B depicts an example of directions of magnetic flux within a pipe as generated by a probe relative to an SSWC anomaly, in embodiments.

FIG. 2A and 2B depict a method for identifying and remediating SSWC in accordance with embodiments.

FIG. 3 depicts a block diagram depicting an SSWC predictor, in embodiments.

FIG. 4 is an example graph depicting the results of magnetic flux leakage detection for an anomaly that is SSWC.

### DETAILED DESCRIPTION OF THE EMBODIMENTS

Embodiments herein relate to detection and remediation of selective seam weld corrosion (SSWC) in a conduit that transports fluid such as oil or natural gas products. In particular, these embodiments are useful for distinguishing SSWC from other types of anomalies that can form on the conduit and for providing a systematic response to a significant probability of SSWC being present. Conduits with which embodiments are generally used are envisioned to be pipes made of steel and/or or other metals capable of conducting magnetic flux.

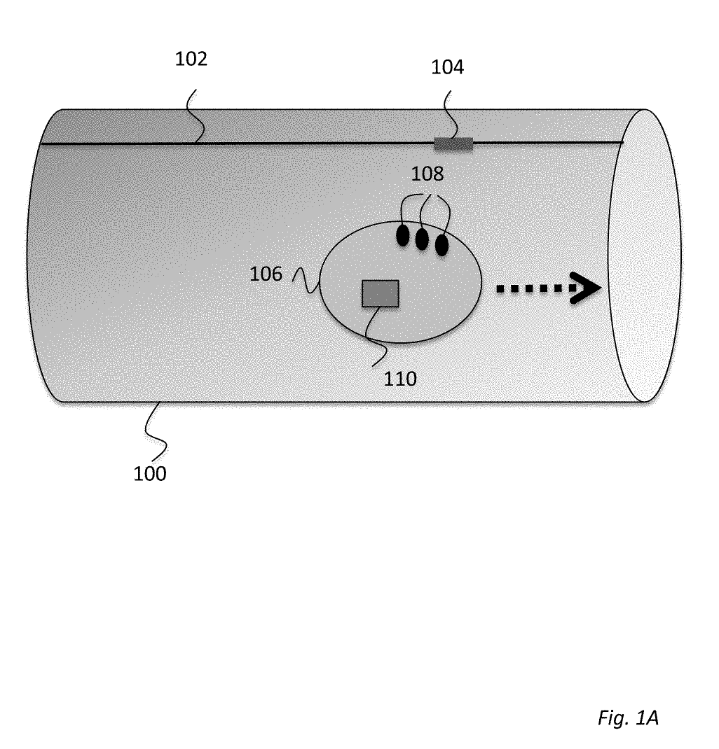

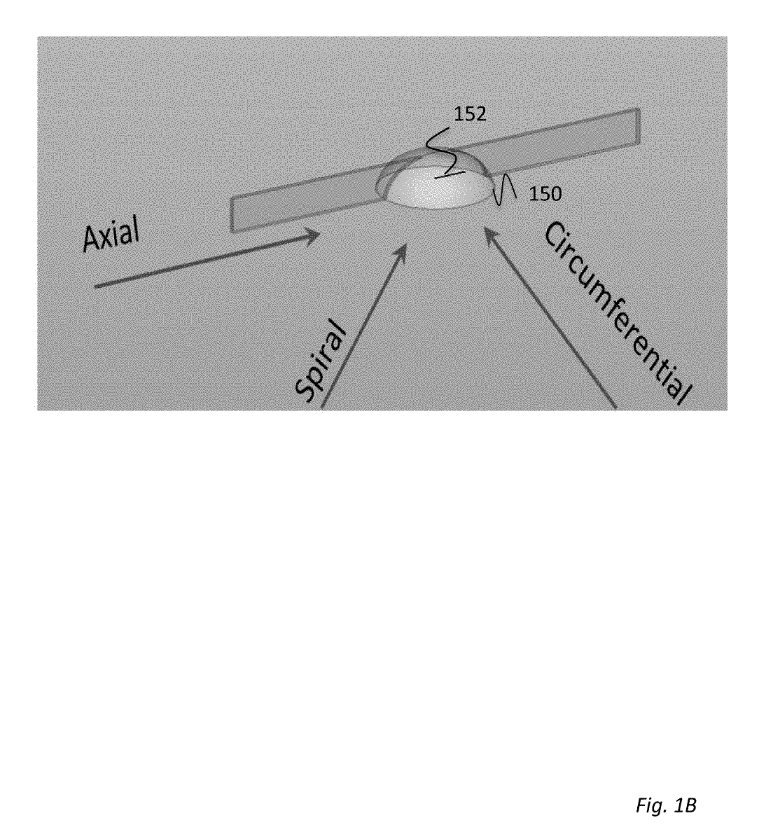

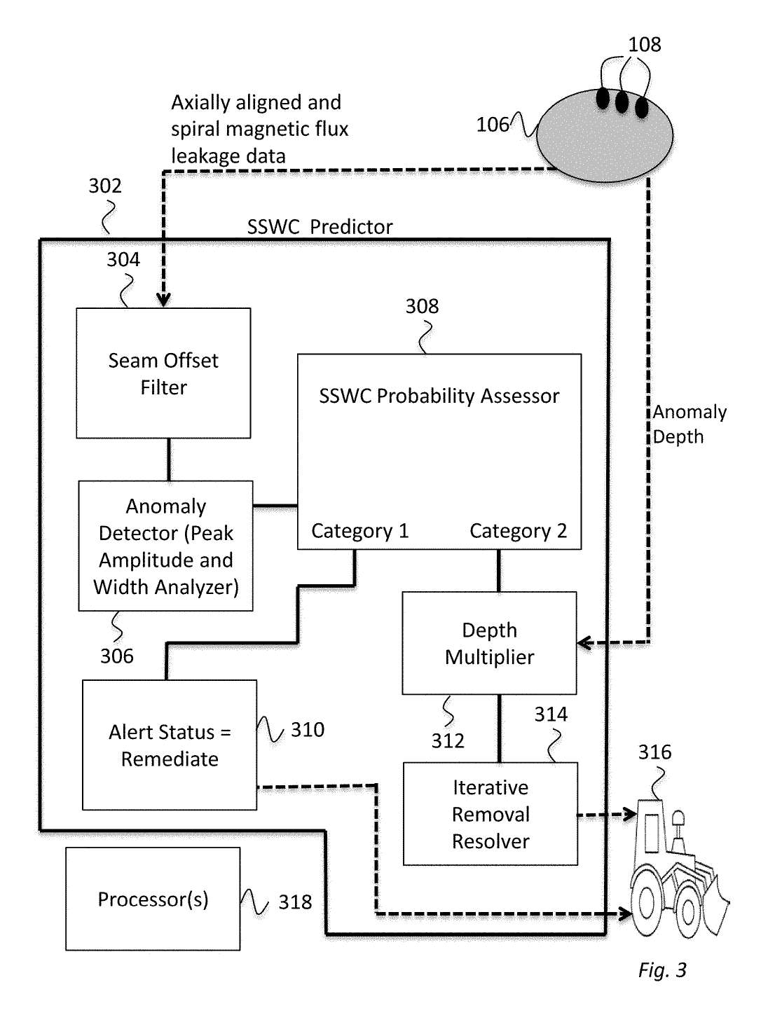

Referring to FIG. 1, to assist in detecting SSWC, embodiments envision a probe 106 is placed into the conduit 100 at an entry point (not shown) and traverses through at least a segment of the conduit 100. As probe 106 travels, it can produce a signal (e.g., a magnetic field, electromagnetic radiation, or sound), which may be alternating or constant, that at least partially traverses a portion of conduit 100. (The mechanism producing the signal is not shown in the figure. In embodiments discussed herein, the produced signal comprises a magnetic field, though concepts described herein can be applied to other types of signals.) One or more detectors 108 can detect the signal, which is processed by a processing unit. In embodiments, the processing unit can be probe processor 110 and, e.g., the SSWC predictor 302 (discussed in conjunction with FIG. 3 below) can be integrated within the probe 106. However, in embodiments discussed below, the SSWC predictor 302 is envisioned to be remote from probe 106. Either way, the processing unit can determine change (e.g., flux loss, frequency change, etc.) in the signal. A change in signal may occur due to a change in the conduit through which the signal traverses. For example, a conduit section having corrosion may scatter and/or absorb signals differently from an uncorroded conduit portion, resulting in loss of signal magnitude, for example. Various techniques are contemplated for forming datasets from the information collected by the probe 106, including 1) mapping, 2) high resolution deformation, 3) axially-aligned magnetic flux leakage detection, and/or 4) spiral magnetic flux leakage detection. In particular, embodiments primarily discussed herein envision that a combination of at least axially-aligned magnetic flux leakage (AMFL) detection and spiral magnetic flux leakage (SMFL) detection are used to detect SSWC. In embodiments, it is contemplated that the probe 106 can be a multi-dataset inline inspection tool such as ones manufactured by T. D. Williamson (TDW) of Tulsa, Okla.

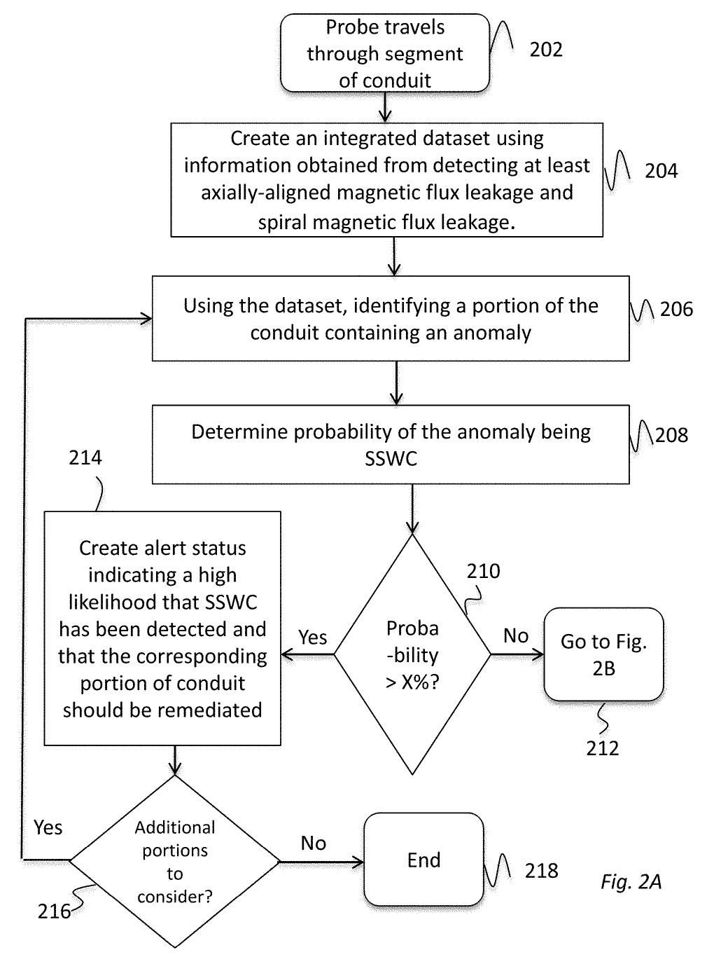

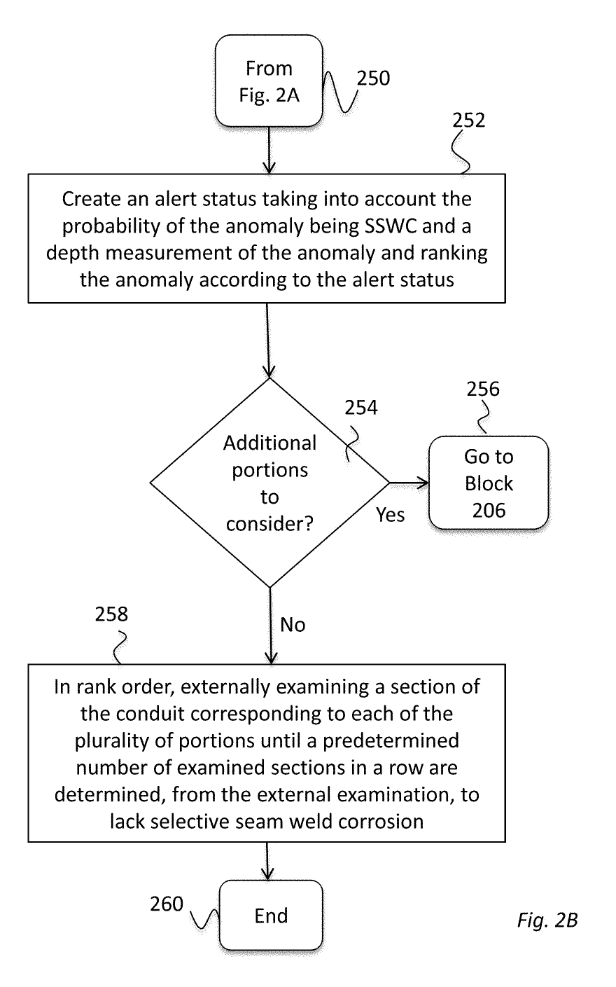

An example method for detecting an anomaly and determining whether it is SSWC is now described with regard to FIGS. 2A and 2B, with additional reference to FIG. 1. Referring first to FIG. 2A, the probe 106 travels through a segment of the conduit 100, as indicated by a block 202. In embodiments, an integrated dataset is created in conjunction with the probe processor 110 within the probe 106 using information obtained from detecting at least AMFL and SMFL. This is shown at block 204. Embodiments also contemplate that probe processor 110 alternatively can create multiple datasets, e.g., one relating to AMFL and the other to SMFL.

The integrated dataset, which may include at least individual AMFL and SMFL datasets referred to above, can be integrated (from the individual datasets) either within the probe 106 or externally. Either way, information regarding the conduit 100 is at some point transferred from the probe 106 and obtained by an external entity (e.g., SSWC predictor 302 discussed below) for further consideration. The obtained integrated dataset (or separate datasets) is then analyzed to identify a portion of the conduit 100 containing an anomaly 104, as indicated by a block 206. (It is assumed for the sake of explanation that at least one anomaly is detected.)

Once an anomaly 104 has been detected, the probability of the anomaly 104 being SSWC is then determined, as indicated by a block 208. In embodiments, the anomaly 104 is analyzed by comparing a portion of the obtained dataset corresponding to the anomaly 104 with a reference dataset (e.g., a model) containing data from, e.g., a known example of SSWC. Depending generally upon how similar the information corresponding to the anomaly 104 is to the reference dataset, a probability of SSWC is assigned to the anomaly 104. In other or overlapping embodiments, this probability can be determined based on whether the portion of the dataset containing the anomaly 104 is within parameters indicative of SSWC (e.g., whether the features of the anomaly have certain proportions or characteristics as reflected by signals received from the probe 106).

It should be understood that, in the example above, the process of identifying an anomaly and assigning a probability of SSWC can also be implemented in a single integrated step. It should further be understood that, in this example, the anomalies are described as being fully analyzed from the integrated dataset in serial. However, embodiments also envision that the analysis can be done in other ways, e.g., all anomalies could be identified prior to any probabilities being assessed.

Once the probability has been assessed, it is determined whether the probability of the anomaly 104 being SSWC is greater than a predetermined percentage X, as indicated by a decision block 210. (In embodiments, X is between 65% and 75%.) If it is greater than X%, an alert status is generated indicating a high likelihood that SSWC has been detected and that the portion of the conduit 100 corresponding to the anomaly 104 should be remediated, typically necessitating one or more of excavation, physical examination removal and replacement of the portion of the conduit having the SSWC. This is shown at block 214. In general, this alert status can be, e.g., a record in a file indicating that the status of the anomaly 104 is one requiring immediate attention (e.g., the status is “immediate attention required”). It can also be a message to a user's screen indicating a high warning level pertaining to the anomaly 104. It should also be understood that the range of 65-75% is just an example and that the percentage can be set to any appropriate number to balance potentially competing concerns (e.g., odds of a conduit failure versus the effort and cost required to remediate an anomaly). Regarding external examination, in embodiments, this is envisioned to include a person physically examining the suspected SSWC after the portion of the conduit in question has been cut open or otherwise accessed.

Once the alert status has been created as indicated above, it is then determined whether there are any additional portions of the conduit 100 to consider, as indicated by a decision block 216. If there are none, the method is finished, as indicated by a block 218. Otherwise, a next portion of the conduit 100 is identified, per block 206.

Returning to decision block 210, if the probability is less than or equal to X%, then the method continues at FIG. 2B (block 250), as indicated by a block 212. As before, an alert status is created for each anomaly, but here it is envisioned that the anomalies are ranked by alert status and then (in accordance with procedures described below) only those portions of the conduit associated with certain ranked anomalies are removed and remediated. More particularly, in embodiments, a depth measurement of the anomaly 104 as well as the probability are taken into account when determining the alert status for these anomalies and, in some embodiments, the equation “Probability X Depth Measurement=alert status” is specifically used. Of course, it should be understood that other parameters can be used to create the alert status, such as the probability by itself In any event, once the alert status has been created, the anomaly at issue is then ranked with regard to other anomalies that have been similarly evaluated. This is depicted by a block 252.

It is then determined whether there are any additional portions of the conduit 100 to consider. This is indicated by a decision block 254. If there are, the method goes back to block 206 (as indicated by block 256).

If there are no additional portions to consider, then beginning with the portion containing the highest ranked anomaly, that portion of the conduit 100 is removed and externally examined for SSWC. This examination continues down the list of all ranked anomalies (in order of descending alert status) until a predetermined number of sections in a row are determined, from the external examination, to lack SSWC. This is indicated by a block 258. In some embodiments, that predetermined number is two.

Various embodiments and aspects thereof are now discussed in greater detail below. In embodiments, the measurements of AMFL and SMFL are each used to create a dataset, each of which may include, at least, a set of spatial values and corresponding signal amplitude values. Signal amplitude values represent the signal (e.g., magnetic flux) detected by detector(s) 108. A change in signal amplitude values represents a change in the signal (e.g., as the probe traverses a conduit from a portion without SSWC to a portion with SSWC). At a particular location of a conduit, an anomaly may lead to one or more peaks in the AMFL and/or SMFL signal datasets. For example, when a conduit portion without SSWC is analyzed, the signal amplitude values may correspond to baseline signal amplitude values (representing background signal, such as background magnetic flux detected by detectors 108). However, when a conduit portion with SSWC is analyzed, signal amplitude values will deviate from the baseline signal amplitude values (e.g., forming one or more peaks positive/negative of the baseline) by some measurable amount. Generally, a peak is a description of the distribution of signal amplitude values versus respective signal spatial values for at least a portion of the dataset. Exemplary parameters (or descriptors) of a peak is width of the peak and the maximum amplitude of the peak.

A variety of methods and/or software packages (e.g., Matlab or Igor Pro) may be used to identify and analyze datasets for peak(s) and baseline(s). It should be understood that a variety of selection criteria or parameters may be selected to determine a peak in a signal dataset (e.g., noise smoothing, noise tolerance, fitting function, signal-to-noise ratio tolerance, etc.).

In embodiments for detecting and remediating SSWC, the following techniques are contemplated. First, an anomaly of interest is detected. In embodiments, this can occur when one or more AMFL signal peaks and one or more SMFL signal peaks are observed at a particular location based on the data received from the probe. Qualitatively, the width of a peak of an AMFL signal reflects the physical width of an anomaly (e.g., SSWC) in the axial direction and the width of a peak of an SMFL signal reflects the physical width of an anomaly (e.g., SSWC) in a helical or spiral direction. For example, the width of an AMFL signal peak at a selected portion of the peak (e.g., peak width where the peak amplitude is 45%, 50%, or 65% of the maximum peak amplitude) corresponds to the physical width of the anomaly. Qualitatively, the maximum amplitude of a peak of an AMFL and/or SMFL signal is a function of the length, width, and depth (or, generally, the shape) of an anomaly. In certain embodiments, the maximum peak amplitude of an AMFL and/or an SMFL signal may depend on anomaly depth to a greater degree than on anomaly length and anomaly width. To then determine if this anomaly of interest is SSWC, the peak width and the peak maximum amplitude are determined for each of the one or more AMFL peaks. Each AMFL peak width, W_{MFL}, is normalized with respect to the pipe wall thickness, tₚᵢₚₑ, to determine a nondimensionalized AMFL peak width,

$${w}_{n , AMFL} = \frac{{w}_{AMFL}}{{t}_{pipe}} .$$

Pipe wall thickness, tₚᵢₚₑ, is the known pipe or pipe section containing the anomaly of interest. Each AMFL peak maximum amplitude, A_{AMFL}, is normalized with respect to the local background axial magnetic flux density, B_{AMFL}, to determine a nondimensionalized AMFL peak amplitude,

$${A}_{n , AMFL} = \frac{{A}_{AMFL}}{{B}_{AMFL}} .$$

At the above location of the anomaly of interest, the peak width and the peak maximum amplitude are then determined for each of the one or more SMFL peaks. Each SMFL peak width, W_{SMFL}, is normalized with respect to the pipe wall thickness, tₚᵢₚₑ, to determine a nondimensionalized SMFL peak width,

$${w}_{n , SMFL} = \frac{{wS}_{MFL}}{{t}_{pipe}} .$$

Each SMFL peak maximum amplitude, B_{SMFL}, is normalized with respect to the local background spiral magnetic flux density, B_{SMFL}, to determine a nondimensionalized SMFL peak maximum amplitude,

$${A}_{n , SMFL} = \frac{{A}_{SMFL}}{{B}_{SMFL}} .$$

The features W_{n,AMFL}, A_{n,AMFL}, W_{n,SMFL}, and A_{n,SMFL} correspond to the input parameters for the SSWC logistic regression model (described below). These features are extracted and determined at a location of each anomaly of interest that is a possible SSWC.

According to embodiments disclosed herein, the SSWC logistic regression model is F(z), where:

$$F ( z ) = \frac{1}{1 + {e}^{- z}} ,$$

Z=β₀+β₁W_{n,AMFL}+β₂W_{n,SMFL}+β₃A_{n,AMFL}+β₄A_{n,SMFL}, and each of β₀, β₁, β₂, β₃, and β₄ is independently an SSWC best fit model coefficient. For each anomaly of interest, the corresponding features W_{n,AMFL}, A_{n,AMFL}, W_{n,SMFL}, and A_{n,SMFL} are input parameters to determine F(z). According to certain embodiments of the methods disclosed herein, the SSWC best fit model coefficients are: β₀=−5.21, β₁=1.08, β₂=−1.90, β₃=5.42, and β₄=9.10. It should be understood that, in at least some embodiments, F(z) can be determined using SMFL data without the need for AMFL data.

F(z) represents the fractional probability that the anomaly of interest, corresponding to the analyzed AMFL and SMFL peaks, is an SSWC. The probability that the anomaly of interest is an SSWC is P_{SSWC}=F(z)×100%. For determining the probability that an anomaly of interest is an SSWC, the value of F(z) is in the range of 0 to 1.0, where the P_{SSWC} is 0% when F(z)=0 and P_{SSWC} is 100% when F(z)=1.0.

As AMFL and SMFL measurements are performed along the length of a pipe or pipe section, the above steps are repeated for each anomaly of interest. Each anomaly of interest is categorized as a “Category 1 SSWC” or a “Category 2 SSWC”. A discrimination threshold is determined such that an anomaly corresponding to a P_{SSWC} greater than the discrimination threshold is categorized as a Category 1 SSWC. An anomaly corresponding to a P_{SSWC} less than or equal to the discrimination threshold is categorized as a Category 2 SSWC. In embodiments, the discrimination threshold is envisioned to be between 65 and 75%, though other threshold levels can also be used. The discrimination threshold may be selected to represent the conservativeness of the SSWC classification, or categorization. A higher discrimination threshold represents a more conservative SSWC classification.

In embodiments, for at least each of the anomalies of interest categorized as a Category 2 SSWC, an SSWC depth, \hat{d}_{SSWC}, is determined. The SSWC depth is: \hat{d}_{SSWC}=β₅\hat{d}_{SMFL}+β₆\hat{d}_{AMFL}, where each of \hat{d}_{SMFL} and \hat{d}_{AMFL} is independently a depth of the anomaly of interest determined from SMFL and AMFL depth sizing models in the TDW analysis software package “Interactive Report”, and each of β₅ and β₆ is a depth best fit model coefficient. According to certain embodiments of the methods disclosed herein, the depth best fit model coefficients are: β₅=0.68 and β₆=0.27. For the determination of the SSWC thickness, the value of interest for \hat{d}_{SSWC} is in the range of 0 to 1.0. The SSWC depth, \hat{d}_{SSWC}, represents the fraction of the pipe wall thickness containing the SSWC. The SSWC depth represented as a percentage is \hat{d}_{p,SSWC}(i.e., \hat{d}_{p,SSWC}=\hat{d}_{SSWC}×100%), which corresponds to the percentage of the pipe wall thickness containing the SSWC. For each Category 2 SSWC anomaly, a Category 2 SSWC Identification Probability, P_{cat2,SSWC}, is determined. The Category 2 SSWC Identification Probability is the product of the probability that an anomaly is an SSWC, P_{SSWC}, and of the SSWC depth, \hat{d}_{p,SSWC}, and it is a percentage value from 0% to 100%:

$${P}_{cat 2 , SSWC} = \frac{{P}_{SSWC} \times {\hat{d}}_{p , SSWC}}{100} .$$

The Category 2 SSWC Identification Probability is thus an SSWC prediction probability that is generally weighted toward anomalies with greater depth. Generally, the Category 2 SSWC Identification Probability may be understood to reflect the severity of an anomaly which may be an SSWC, where severity may be understood to reflect the degree to which a conduit seam (e.g., seam weld) is compromised at a given location of the conduit (e.g., pipe).

For each Category 1 SSWC, an alert status is sent to indicate the respective pipe or pipe section (having the respective anomaly of interest categorized as a Category 1 SSWC) should be extracted and inspected/remediated within a certain number of days (e.g., 180) from the time of measurement. In embodiments, this alert status can be in the form of an alarm or other notification that the pipe section should be removed or a list of such Category 1 anomalies. For those anomalies with particularly high probability and/or depth numbers, a separate category is envisioned where a user is warned of an especially high risk/likelihood of rupture of the pipe section (e.g., where the probability is greater than 90%) so that remediation measures can be implemented on an even more expedited basis.

Each Category 2 SSWC anomaly is listed and ranked, in descending order, according to its P_{cat2,SSWC} starting with the greatest P_{cat2,SSWC}. Starting with the pipe or pipe section having the Category 2 SSWC with the greatest P_{cat2,SSWC} and in order of descending P_{cat2,SSWC}, in embodiments, each pipe or pipe section is extracted and remediated/inspected, within a certain number of days from the time of measurement, until two consecutive inspected pipe and/or pipe sections, having a Category 2 SSWC, are found upon physical inspection to be without SSWC. After two consecutively ranked and inspected pipe or pipe sections having a Category 2 SSWC are found to be without SSWC, no more extractions/inspections are implemented. Of course, it should be understood that a different number of extractions and inspections can be implemented prior to ceasing the extraction/excavation process. In addition, in at least some embodiments, Category 2 SSWC anomalies can be listed and ranked using only the probability determinations (i.e., using only P_{SSWC}).

Embodiments are now further described with regard to the block diagram of FIG. 3. Referring to FIG. 3, probe 106 is shown sending AMFL and SMFL data (e.g., datasets) to an SSWC predictor 302. The SSWC predictor 302 determines whether a section of conduit should be analyzed in greater detail as indicated above. While the conduit is often underground and thus needs to be excavated, it should be understood that, in embodiments, the conduit can also be above ground, in which case it needs to be cut open or otherwise extracted/entered for closer internal inspection, typically after shutting off whatever is being transported within it.

In embodiments, the AMFL data is received as a dataset separate from the SMFL data (though as mentioned above, it can also be received as an integrated dataset). It is envisioned that the SSWC predictor 302 comprises several components as discussed below which, in embodiments, reside as computer-readable instructions in one or more memory/storage devices (not shown). It is further envisioned that these components utilize one or more processors (predictor processors) 318. In embodiments, processor(s) 318 may represent one or more digital processors. Memory/storage may represent one or both of volatile memory (e.g., RAM, DRAM, and SRAM, and so on) and non-volatile memory (e.g., ROM, EPROM, EEPROM, Flash memory, magnetic storage, optical storage, network storage, and so on). Memory/storage includes machine readable instructions that are executed by processor(s) 318 to provide the functional aspects of SSWC predictor 302 as described herein. SSWC predictor 302 or aspects thereof may be part of a company such as Koch Industries or in communication with such a company.

Only data relating to parts of the conduit that are close to the seam warrant analysis for SSWC. Thus, in embodiments, a seam offset filter 304 filters out data from both the spiral and axially-aligned datasets that are not within a certain distance from the pipe seam. For example, only data that is plus or minus 1 inch on either side of the seam from the perspective of the probe will be further analyzed.

In embodiments, an anomaly detector 306 receives the two datasets and, for each dataset, determines whether any portion of the data (corresponding to a particular conduit location) has, for example, a peak maximum amplitude and/or peak width corresponding to at least predetermined limits (and/or, in embodiments, determines the existence of a predetermined peak maximum amplitude/peak width ratio). As indicated previously, this is used to indicate the existence of an anomaly of interest at a particular location. In particular, detection of an anomaly of interest is considered to exist when significant (uncharacteristic) peak maximum amplitude and/or peak width readings (or some ratio thereof) occur within both datasets corresponding to a given location of the conduit. (It is thus envisioned that within the datasets is information used to identify the location of any anomaly of interest within the conduit).

When an anomaly of interest is detected, the data relating to that anomaly is sent to an SSWC probability assessor 308 to determine the probability of the anomaly being SSWC. The anomaly can be sent to SSWC probability assessor 308 when the anomaly is first detected or in batch after multiple anomalies have been detected by anomaly detector 306. It should be understood that the datasets from the probe 106 can also be fed directly into SSWC probability assessor 308 without the use of the anomaly detector 306 or seam offset filter 304. However, various efficiencies may be achieved by only sending data relating to anomalies of interest as described above into the SSWC probability assessor 308.

In embodiments, the SSWC probability assessor 308 receives the data sets and predicts the probability of each anomaly of interest being an SSWC, which may be done in the manner described above. When the probability of an anomaly being SSWC is above a preset threshold level (e.g., 70%), it is categorized as a “category 1” SSWC. This means that it is sufficiently likely that the anomaly is, indeed, SSWC that the section of pipe containing that anomaly should be removed/remediated, and thus an alert status of “remediate” 310 (or the like) is associated with that anomaly. The portion of the pipe associated with the anomaly is then removed and typically replaced.

Those anomalies of interest having a probability of less than the preset threshold level are categorized as a “category 2” SSWC, where additional efforts are needed to determine whether the anomaly is, in fact, an SSWC and thus whether removal of a portion of the conduit is warranted. In embodiments, the depth of each anomaly of interest is ascertained and, for each category 2 SSWC, combined in some manner with the probability assigned to the anomaly by the SSWC probability assessor 308. In particular, embodiments envision that, for each category 2 SSWC, the probability (as assigned by the probability assessor 308) is multiplied by the depth of the anomaly and that resultant product is assigned to the anomaly. These category 2 SSWCs and their associated resultant products are then sorted in descending order and used by an iterative removal resolver 314 to indicate which anomalies are associated with the highest resultant products. In embodiments, portions of the conduit associated with the category 2 SSWCs are then selected for removal, starting with the portion associated with the largest resultant product and continuing to remove each category 2 SSWC in descending order. After each removal, the anomaly is inspected for SSWC in the manner indicated above. After a predetermined number of inspections with category 2 SSWC uncover no actual SSWC, the removal process is discontinued, since it becomes less likely that the remaining category 2 SSWC anomalies are, in fact, real SSWC that warrant removal/excavation. This technique allows dangerous SSWC to be detected in a more accurate and efficient manner than has previously been possible. In embodiments, the aforementioned predetermined number is 2, though a higher number can be used to be more conservative but at greater expense.

It should be understood that various embodiments envision that iterative removal resolver 314 can utilize the probability information from the SSWC probability assessor 308 without the need for the depth multiplier 312.

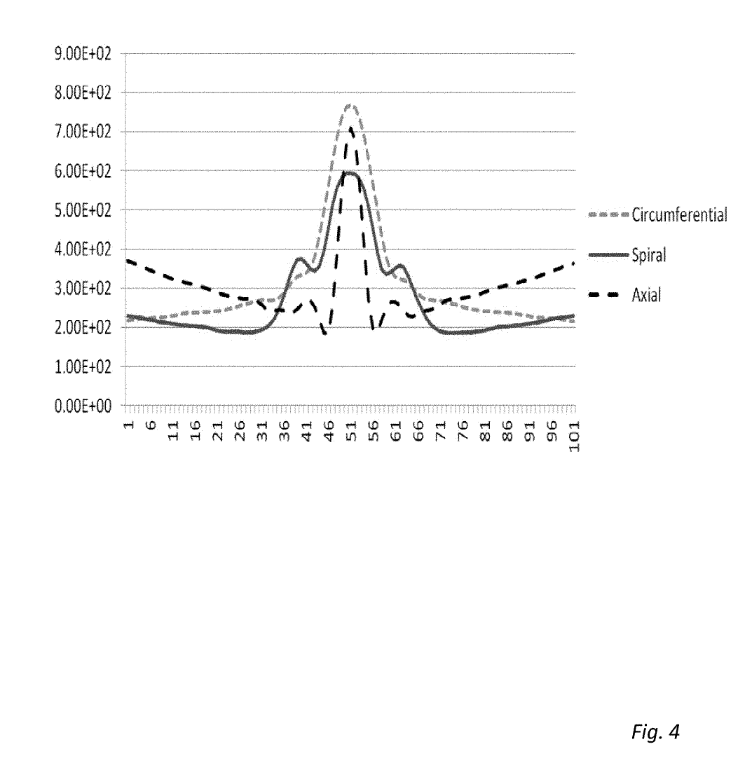

FIG. 4 is a graph depicting the results of magnetic flux leakage detection from three different datasets for an anomaly that is SSWC. Here, the datasets represent axial, spiral and circumferential leakage. The X axis represents location within a conduit and the Y axis is a magnetic field measurement. The particular amplitude and width measurements for each dataset over a particular portion of the conduit is indicative of SSWC. As indicated herein, all three datasets are not required for detection of SSWC using the techniques described above, and in embodiments, only axial and spiral leakage detection are utilized.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A method for detecting selective seam weld corrosion in a conduit, comprising, receiving a dataset, the dataset containing information obtained from a probe traversing at least a segment of the interior of the conduit and detecting at least one of an electromagnetic, magnetic and sound-related occurrence from an area of the conduit in proximity to a conduit seam;
identifying, from the dataset, a portion of the conduit containing an anomaly;
analyzing the anomaly to determine the presence of selective seam weld corrosion by at least one of:
a) comparing the dataset with a reference dataset containing data indicative of selective seam weld corrosion, and
b) determining whether aspects of the dataset are within parameters indicative of selective seam weld corrosion; and
generating an alert status corresponding to the anomaly, wherein the alert status is indicative of potential selective seam weld corrosion within the portion of the conduit and is determined by results from the step of analyzing.

2. The method of claim 1, wherein the dataset obtained from the probe comprises axially-aligned magnetic flux leakage and spiral magnetic flux leakage information.

3. The method of claim 1, wherein the alert status is generated using a probability, as determined by step of analyzing, that the anomaly is selective seam weld corrosion

4. The method of claim 3, wherein the anomaly in the portion of the conduit is identified, by the alert status, as having a high likelihood of being selective seam weld corrosion when the probability is greater than 70%.

5. The method of claim 4, further comprising receiving a warning signal to promptly remediate a section of the conduit where the anomaly having an especially high likelihood of selective seam weld corrosion is identified.

6. The method of claim 3, wherein the alert status is generated using a depth measurement of the anomaly.

7. The method of claim 6, wherein the alert status is generated by multiplying the probability by the depth measurement of the anomaly.

8. The method of claim 6, further comprising:
a) identifying a plurality of portions of the conduit containing an anomaly where the probability of the anomaly being selective seam weld corrosion is less than or equal to a predetermined percentage,
b) ranking each anomaly in the plurality of the portions according to factors including the probability of containing selective seam weld corrosion and the depth measurement, and
c) in an order of said ranking, externally examining a section of the conduit corresponding to each of the plurality of portions until a predetermined number of consecutively examined sections are determined, from the external examination, to lack selective seam weld corrosion.

9. The method of claim 8, wherein the predetermined percentage is between 65% and 75%.

10. A system for detecting selective seam weld corrosion in a conduit, comprising, a probe, the probe constructed to traverse at least a segment of the interior of the conduit and comprising sensors capable of detecting magnetic flux leakage in at least a first and second orientation in proximity to a conduit seam of the conduit;
a probe processor, the probe processor creating at least one dataset, the at least one dataset based on detection of magnetic flux leakage in the first and second orientation;
one or more predictor processors in communication with one or more memory devices, the one or more memory devices containing computer-readable instructions that, when executed by the one or more predictor processors, can operate to:
receive the dataset;
identify, from the dataset, a portion of the conduit containing an anomaly;
analyze the anomaly to determine the presence of selective seam weld corrosion by operating to:
a) compare the dataset with a reference dataset containing data indicative of selective seam weld corrosion, and
b) determine whether aspects of the dataset are within parameters indicative of selective seam weld corrosion; and
generate an alert status corresponding to the anomaly, wherein the alert status is indicative of potential selective seam weld corrosion within the portion of the conduit and is determined by results from the step of analyzing.

11. The system of claim 10, wherein the probe processor creates at least a first and second dataset, the first dataset based on detection of magnetic flux leakage in the first orientation and the second dataset based on detection of magnetic flux leakage in the second orientation.

12. The system of claim 10, wherein the dataset obtained from the probe comprises axially-aligned magnetic flux leakage and spiral magnetic flux leakage information.

13. The system of claim 10, wherein the alert status is generated using a probability that the anomaly is selective seam weld corrosion

14. The system of claim 13, wherein the anomaly in the portion of the conduit is identified, by the alert status, as having a high likelihood of being selective seam weld corrosion when the probability is greater than 70%.

15. The system of claim 14, further comprising receiving a warning signal to promptly remediate a section of the conduit where the anomaly having an especially high likelihood of selective seam weld corrosion is identified.

16. The system of claim 13, wherein the alert status is generated using a depth measurement of the anomaly.

17. The system of claim 16, wherein the alert status is generated by multiplying the probability by the depth measurement of the anomaly.

18. The system of claim 16, further comprising computer-readable instructions that operate to:
a) identify a plurality of portions of the conduit containing an anomaly where the probability of the anomaly being selective seam weld corrosion is less than or equal to a predetermined percentage,
b) rank each anomaly in the plurality of the portions according to factors including the probability of containing selective seam weld corrosion and the depth measurement, and
c) in an order of said ranking, determine which section of the conduit to continue to externally examine corresponding to each of the plurality of portions until a predetermined number of consecutively examined sections are determined, from the external examination, to lack selective seam weld corrosion.

19. The method of claim 18, wherein the predetermined percentage is between 65% and 75%.

20. A system for detecting selective seam weld corrosion in a conduit, comprising one or more predictor processors in communication with one or more memory devices, the one or more memory devices containing computer-readable instructions that, when executed by the one or more predictor processors, can operate to:
receive at least one dataset, the at least one dataset containing information obtained from a probe traversing at least a segment of the interior of the conduit and detecting magnetic flux leakage in at least two different orientations relative to and in proximity to a conduit seam of the conduit;
identify, from the dataset, a portion of the conduit containing an anomaly;
analyze the anomaly to determine the presence of selective seam weld corrosion by operating to:
a) compare the dataset with a reference dataset containing data indicative of selective seam weld corrosion, and
b) determine whether aspects of the dataset are within parameters indicative of selective seam weld corrosion; and
generate an alert status corresponding to the anomaly, wherein the alert status is indicative of potential selective seam weld corrosion within the portion of the conduit and is determined by results from the step of analyzing.
